(19) United States
(12) Patent Application Publication
(10) Pub. No.: US 2026/0190379 A1
(43) Pub. Date: Jul. 2, 2026

(54) SEMICONDUCTOR STRUCTURE AND METHOD OF FORMING THE SAME

(71) Applicant: TAIWAN SEMICONDUCTOR MANUFACTURING COMPANY LTD., HSINCHU (TW)

(72) Inventors: KAU-CHU LIN, TAICHUNG CITY (TW); CHAN-YU HUNG, TAINAN CITY (TW); FEI-YUN CHEN, HSINCHU (TW); CHING-HSIUNG HSU, HSINCHU COUNTY (TW)

(21) Appl. No.: 19/006,274

(22) Filed: Dec. 31, 2024

(51) Int. Cl. H10D 30/62; H01L 21/762; H10D 30/01; H10D 80/20; H10D 84/01; H10D 84/03; H10D 84/83

(52) U.S. Cl. CPC H10D 30/62; H10D 30/024; H10D 84/013; H10D 84/0158; H10D 84/834; H10W 10/014; H10W 10/17; H10D 80/251; H10D 84/038

(57) ABSTRACT

A semiconductor structure and a method of forming the semiconductor structure are provided. The method includes: receiving a semiconductor substrate; forming a first well region and a second well region within the semiconductor substrate; forming a first dielectric layer on the semiconductor substrate between the first well region and the second well region; forming an interconnect structure comprising a second dielectric layer over the semiconductor substrate; and depositing a conductive layer in the interconnect structure over the second dielectric layer. The conductive layer serves as a first gate electrode of a first transistor in a first zone of the semiconductor substrate.

### BACKGROUND

High-voltage transistors are widely used in modern semiconductor devices, e.g., power management integrated circuits (PMIC). The high-voltage transistors are generally designed to operate under a high voltage, e.g., voltage greater than five volts, 10 volts or above, as compared to a low-voltage transistor. A high-voltage transistor is generally formed for withstanding a relatively high breakdown voltage during operation. As such, an isolation structure is often adopted in the channel near the drain terminal for the high-voltage transistor to withstand the high electric field generated by the high voltage supplied to the drain terminal.

### BRIEF DESCRIPTION OF THE DRAWINGS

Aspects of the embodiments of the present disclosure are best understood from the following detailed description when read with the accompanying figures. It is noted that, in accordance with the standard practice in the industry, various structures are not drawn to scale. In fact, the dimensions of the various structures may be arbitrarily increased or reduced for clarity of discussion.

FIGS. 1A to 1Q are cross-sectional views of intermediate stages of a method of forming a semiconductor device, in accordance with some embodiments of the present disclosure.

FIG. 2 shows a plan view of a high-voltage transistor, in accordance with some embodiments of the present disclosure.

FIG. 3 shows a flowchart of a method of manufacturing a semiconductor device, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, although the terms such as “first,” “second” and “third” describe various elements, components, regions, layers and/or sections, these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the deviation normally found in the respective testing measurements. Also, as used herein, the terms “about,” “substantial” or “substantially” generally mean within 10%, 5%, 1% or 0.5% of a given value or range. Alternatively, the terms “about,” “substantial” or “substantially” mean within an acceptable standard error of the mean when considered by one of ordinary skill in the art. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “about,” “substantial” or “substantially.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as being from one endpoint to another endpoint or between two endpoints. All ranges disclosed herein are inclusive of the endpoints, unless specified otherwise.

High-voltage (HV) transistors have been widely adopted in power-related applications. An important feature of the HV transistors is its high breakdown voltage for withstanding a high operation voltage applied to the transistor in the turn-on or turn-off state. Generally, a relatively thick gate dielectric layer is arranged between the channel and the gate electrode to withstand a high operation voltage. Further, a buried isolation region, which is usually referred to as a shallow trench isolation (STI) structure, is employed between the drain region and the gate dielectric layer or between the source region and the gate dielectric layer to increase the capability of withstanding high breakdown voltage for the HV transistor. However, the goal of the high-voltage operation with such arrangement is achieved at the cost of the lifted turn-on resistance R_{ds(ON)} between the drain region and the source region and the decreased operation current during the turn-on state of the HV transistor.

The present disclosure discusses a new HV transistor structure to maintain the capability of high-voltage operation while improving the turn-on resistance R_{ds(ON)} and simplifying the manufacturing procedure and cost. A field plate formed in an interconnect structure over the substrate is proposed to serve as the gate electrode of the HV transistor. An inter-metal dielectric (IMD) layer formed between the substrate and the field plate is used as at least part of a gate dielectric layer of the HV transistor. Thus, the existing thick gate dielectric layer and the buried isolation region used for preventing breakdown can be replaced with the IMD layer and a thin gate dielectric layer formed in the substrate. The formation of this thin gate dielectric layer is simpler and more cost effective than the exiting think gate dielectric layer. The electric field between the high-voltage drain region and the low-voltage gate electrode can be adjusted by the field plate so that the areas with a peak electric field intensity around the thin gate dielectric layer can be reduced accordingly. Further, such thin gate dielectric layer can be formed during a formation of the gate dielectric layer of medium-voltage (MV) transistors, thereby saving the processing time and cost of an extra lithography operation in an exiting procedure of forming the gate dielectric layer of the HV transistor. Moreover, since the proposed HV transistor structure can be formed without the bulky STI structure between the gate dielectric layer and the drain region, the device footprint can be decreased. Another feature of the proposed HV transistor is that the turn-on resistance R_{ds(ON)} can be reduced since the intervening buried isolation region between the gate dielectric layer and the drain region is removed, reducing the effective channel length and the corresponding channel resistance of the HV transistor. The performance and processing cost of the HV transistor can thus be improved.

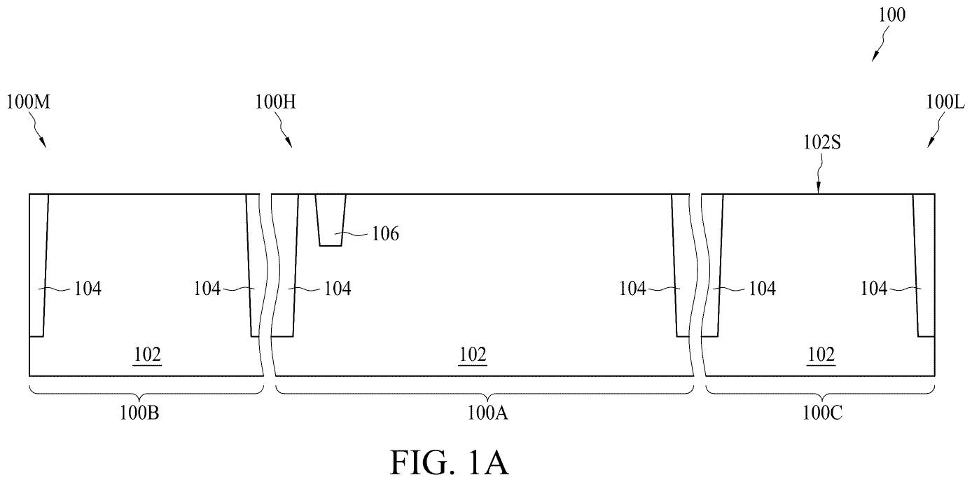

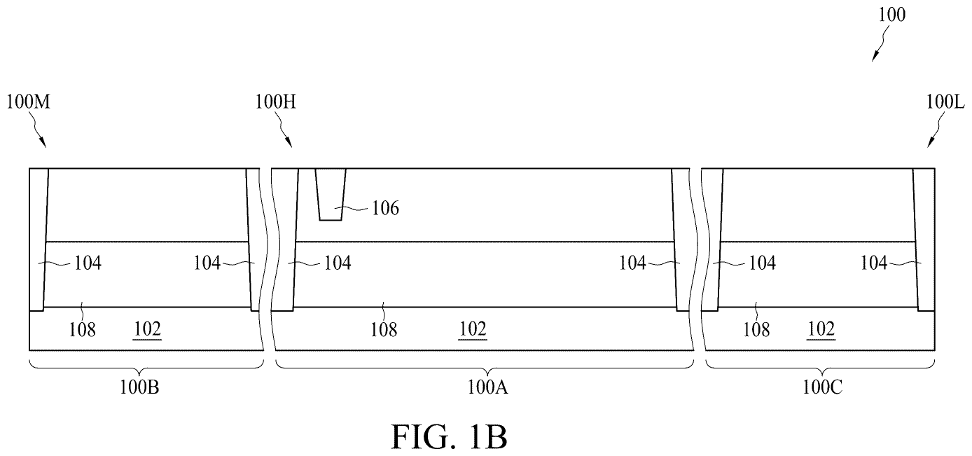

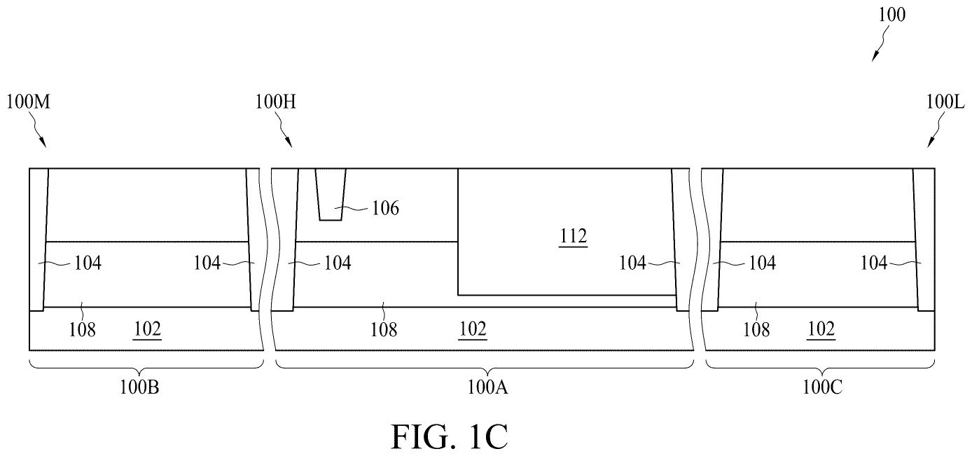

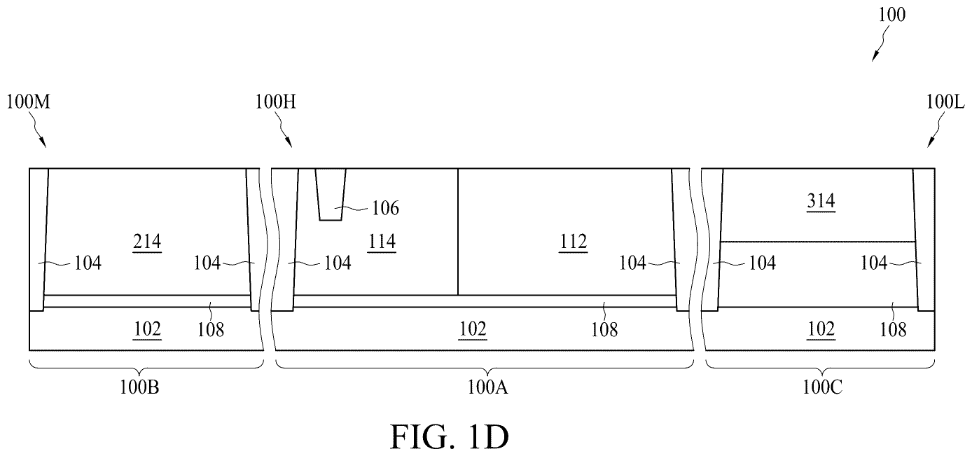

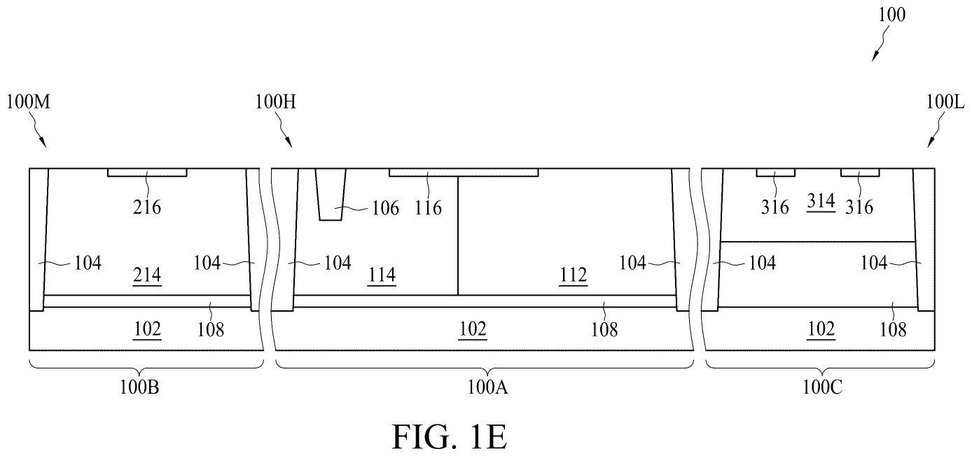

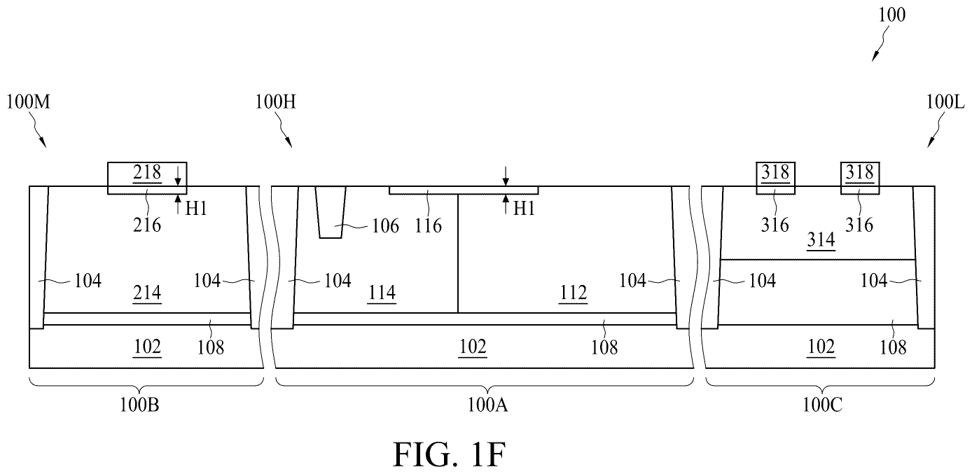

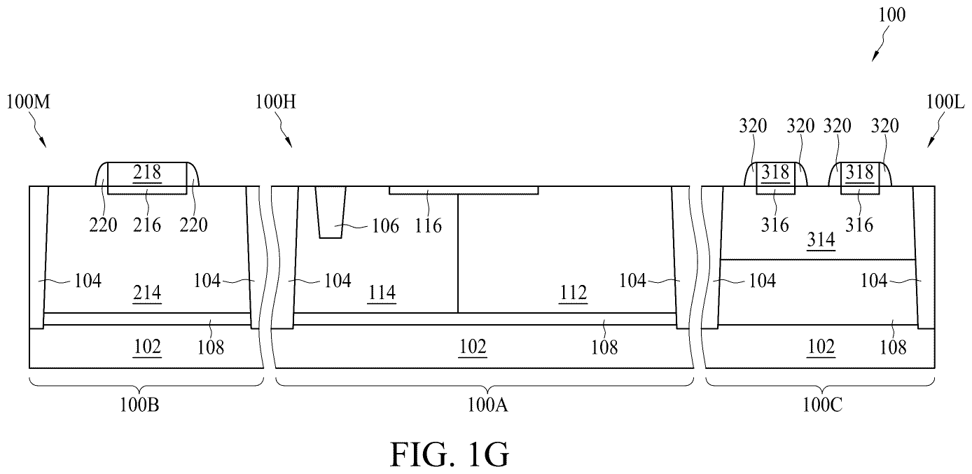

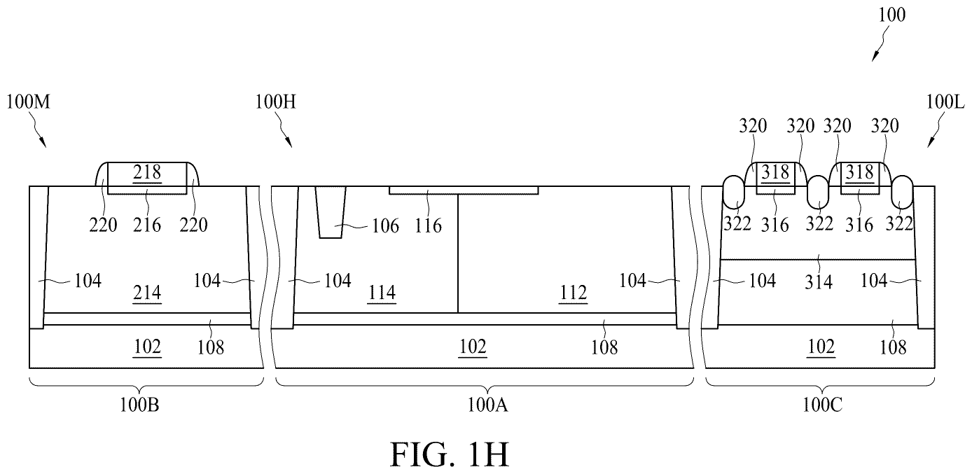

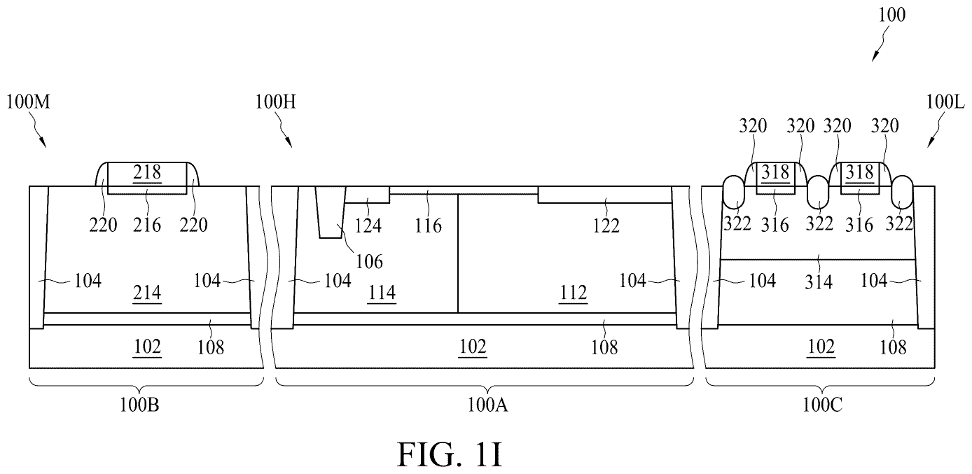

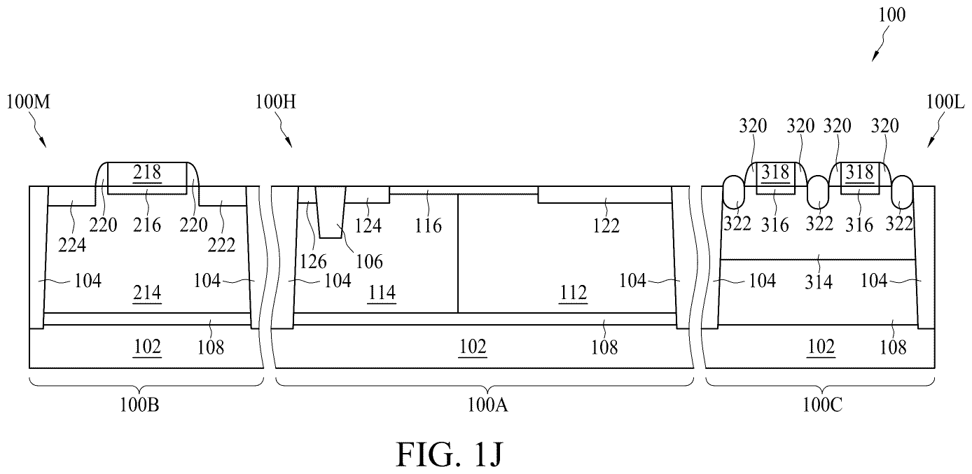

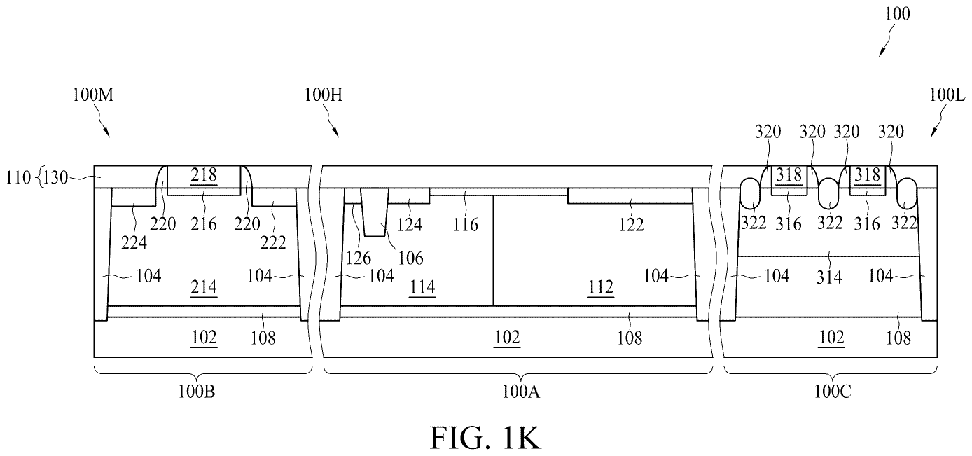

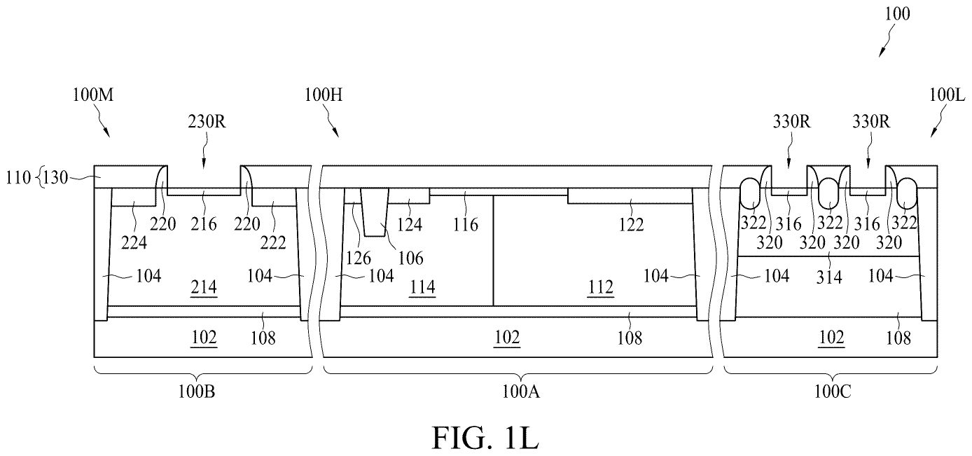

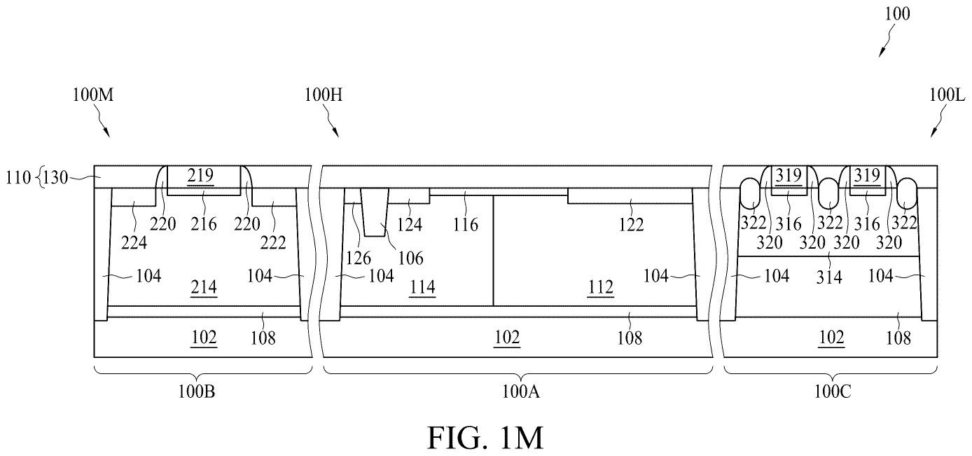

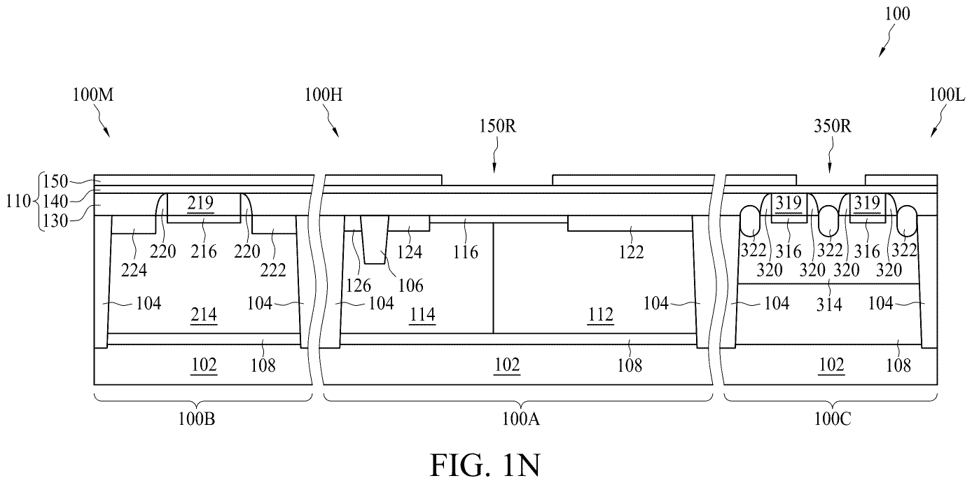

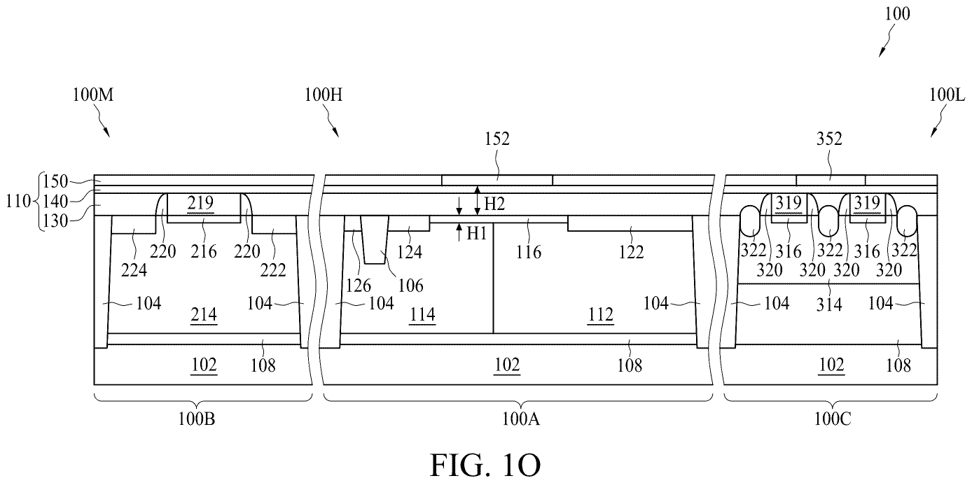

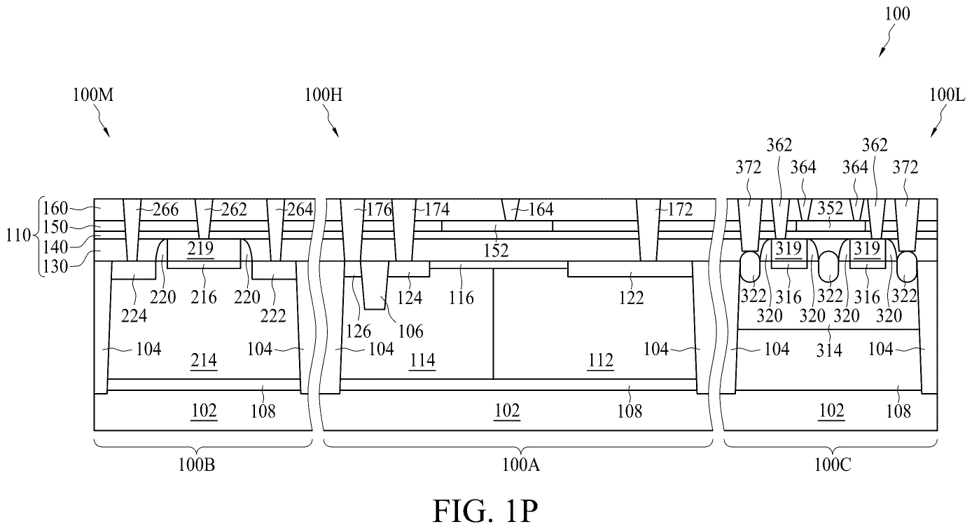

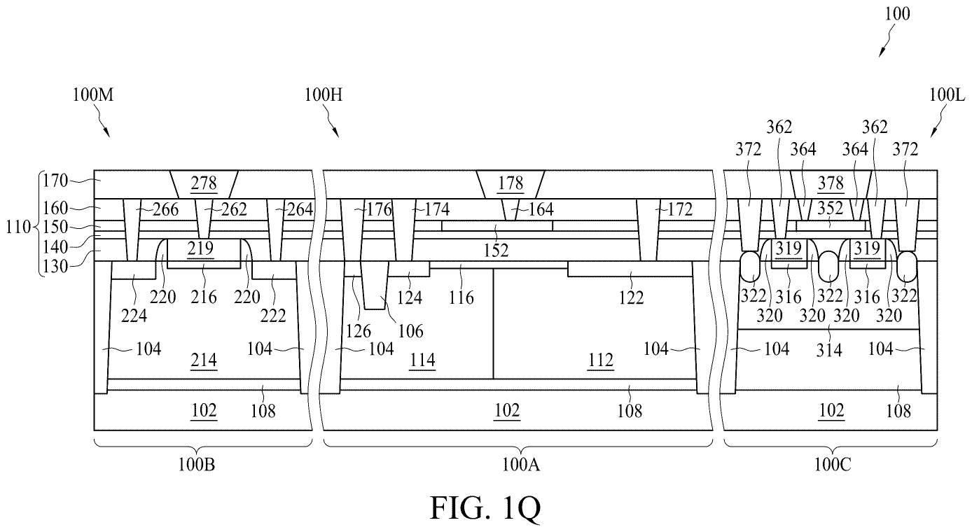

FIGS. 1A to 1Q are cross-sectional views of intermediate stages of a method of forming a semiconductor device 100, in accordance with some embodiments of the present disclosure. In some embodiments, the semiconductor device 100 includes at least three zones 100A, 100B and 100c for accommodating transistors of different operation voltages. The transistors of the semiconductor device 100 may include metal-oxide semiconductor (MOS) field-effect transistors (FETs). In some embodiments, the zone 100A is referred to herein as an HV zone, and includes HV transistors, e.g., an exemplary HV transistor 100H. In some embodiments, the zone 100C is referred to herein as a low-voltage (LV) zone, e.g., one or more low-voltage (LV) zones, and includes LV transistors, e.g., an exemplary LV transistor 100L. The zone 100B is referred to herein as a medium-voltage (MV) zone, and includes MV transistors, e.g., MV transistors 100M. Throughout the present disclosure, the term “HV transistor” refers to a transistor, e.g., a bipolar CMOS DMOS (BCD) transistor, that operates in a relatively high voltage range, e.g., the voltage may be greater than 5 volts, 10 volts, 20 volts, 30 volts or higher, and terms “LV transistor” refers to an LV transistor that operates in a medium or low operation voltage range, e.g., the operation voltage lower than that of the HV transistor, such as lower than about 2 volts. Moreover, the terms “MV transistor” refers to an MV transistor that operates in a medium or low operation voltage range, e.g., the operation voltage between that of the HV transistor and the LV transistor, such as between about 2 volts and about 5 volts. In some embodiments, the operation voltage ranges for the various types of transistors, e.g., the HV transistor, the MV transistor, and the LV transistor, are varying based on different applications. In some embodiments, the operation voltage of the HV transistor is no less than that of the MV transistor, and the operation voltage of the MV transistor is no less than that of the LV transistor. The category of the three types of transistors as discussed above is shown for illustration purposes. The semiconductor device 100 can include more than three zones for accommodating more than two types of transistors of the respective operation voltage ranges.

Referring to FIG. 1A, a semiconductor substrate 102 is provided or formed. In some embodiments, the semiconductor substrate 102 includes semiconductor material such as bulk silicon. In some embodiments, the semiconductor substrate 102 includes other semiconductor materials, such as silicon germanium, silicon carbide, gallium arsenide, or the like. In the present embodiment, the semiconductor substrate 102 is a P-type semiconductive substrate (acceptor type). In some other embodiments, an N-type semiconductive substrate (donor type) 102 can be used. Alternatively, the semiconductor substrate 102 includes another elementary semiconductor, such as germanium; a compound semiconductor including gallium arsenic, gallium phosphide, indium phosphide, indium arsenide, or indium antimonide; an alloy semiconductor including SiGe, GaAsP, AlInAs, AlGaAs, GaInAs, GaInP, or GaInAsP; or combinations thereof. In yet another embodiment, the semiconductor substrate 102 includes portions to form a semiconductor-on-insulator (SOI) substrate. In other alternatives, the semiconductor substrate 102 may include a doped epitaxial layer, a gradient semiconductor layer, and/or a semiconductor layer overlaying another semiconductor layer of a different type, such as a silicon layer on a silicon germanium layer.

A plurality of isolation regions 104 are formed on an upper surface 102S of the semiconductor substrate 102. The isolation regions 104 may include electrically insulating materials or dielectric materials, such as silicon oxide; however, other dielectric materials, e.g., silicon nitride, silicon oxynitride, silicon carbide, silicon oxynitride, or the like, are also possible for forming the isolation regions 104. In some embodiments, the isolation regions 104 are referred to as shallow trench isolation (STI) structures.

In an exemplary procedure of forming the isolation regions 104, a plurality of trenches (not separately shown) are etched from the upper surface 102S of the semiconductor substrate 102. The trenches are formed on the upper surface 102S in the HV zone 100A, the MV zone 100B and the LV zone 100C. The trenches may have substantially equal depths measured from the upper surface 102S. The trenches may be formed using a dry etch, a wet etch, a reactive ion etch (RIE), a combination thereof, or the like. The trenches are filled with the dielectric materials to form the isolation regions 104 using, e.g., chemical vapor deposition (CVD), physical vapor deposition (PVD), atomic layer deposition (ALD), oxidation, nitridation, in-situ steam generation (ISSG), spin-on coating, or other suitable deposition methods.

After the dielectric material of the isolation region 104 fills the trenches, a planarization operation, e.g., chemical mechanical polishing (CMP) or mechanical grinding, may be adopted to remove excess dielectric materials over the upper surface 102S of the semiconductor substrate 102 and level the surface 102S of the isolation regions 104 with the upper surface 102S of the semiconductor substrate 102.

In some embodiments, the isolation regions 104 are formed within the HV zone 100A and at the boundary of the HV zone 100A, MV zone 100B and the LV zone 100C for defining the boundary of different doped regions or well regions in the zones 100A, 100B and 100C or the boundary of each transistor in the respective zones 100A, 100B and 100C. The isolation regions 104 may also be configured to electrically isolate adjacent HV transistors 100H, MV transistors 100M and LV transistors 100L.

An isolation region 106 is formed within an active area (or referred to as an oxide definition (OD) area). The isolation region 106 serves as an isolation region in the HV transistor 100H for improving the performance in a high operation voltage. According to some embodiments, the isolation region 106 has a depth less than a depth of the isolation regions 104.

Referring to FIG. 1B, a well region 108 is formed in the semiconductor substrate 102. The well region 108 is formed in a lower portion at a depth of the semiconductor substrate 102. The well region 108 is also referred to herein as a buried layer. Furthermore, the well region 108 is configured as an isolation layer such that noise resulting from different circuits arranged in other areas (not shown) of the semiconductor substrate 102 may be shielded by the well region 108. Thus, the electrical performance of the HV transistor 100H, MV transistor 100M and LV transistor 100L may be ensured. In an embodiment, the well region 108 is doped with an N-type dopant in a P-type semiconductor substrate 102. Thus, the well region 108 is also referred to herein as a deep N-well. In some embodiments, the well region 108 is present only in the HV zone 100A for the HV transistors 100H. In some embodiments, the MV zone 100B or the LV zone 100C is not used for accommodating HV transistors, and thus is free of any of deep well regions. The depth and profile of the well region 108 are controlled by the recipes of the ion implantation operation. In some embodiments, the ion implantation operation may use N-type dopants, e.g., phosphor, with an implant dose in a range between about 1E12 atoms per square centimeter and about 1E18 atoms per square centimeter.

Referring to FIG. 1C, a well region 112 is formed in the semiconductor substrate 102 over the well region 108. The well region 112 is formed as a doped region at the top portion of the semiconductor substrate 102. In some embodiments, the well region 112 is formed over the underlying well region 108. In some embodiments, the well region 112 is an N-type well region. The well region 112 may be formed using an ion implantation operation. The depth and profile of the well region 112 are controlled by the recipes of the ion implantation operation. In some embodiments, the ion implantation operation may use N-type dopants, e.g., phosphor and arsenic, with an implant dose in a range between about 1E12 atoms per square centimeter and about 1E18 atoms per square centimeter.

Referring to FIG. 1D, a well region 114 is formed in the semiconductor substrate 102 in the HV zone 100A adjacent to the well region 112. Further, a well region 214 is formed in the MV zone 100B, and a well region 314 is formed in the LV zone 100C. The well regions 114, 214 and 314 are formed as doped regions at the top portions of the semiconductor substrate 102. In some embodiments, the well regions 114, 214 and 315 are formed over the underlying well region 108. In some embodiments, the well regions 114, 214 and 314 are P-type well regions. The well regions 114, 214 and 314 may be formed using an ion implantation operation. The depths and profiles of the well regions 114, 214 and 314 are controlled by the recipes of one or more ion implantation operations. In some embodiments, the ion implantation operation may use P-type dopants, e.g., boron, with an implant dose in a range between about 1E12 atoms per square centimeter and about 1E18 atoms per square centimeter. The well region 114 laterally surrounds the isolation region 106. According to some embodiments, the steps shown in FIG. 1C and FIG. 1D are interchangeable, and the order of forming the doped regions 114, 214 and 314 are interchangeable if they are not formed through a same forming operation.

According to some embodiments, the LV transistor 100L is a fin-type FET (FinFET), and a plurality of fins are formed prior to the formation of the well region 108 or prior to the formation of the well regions 314. These fins are formed by etching the semiconductor substrate 102 from the upper surface 102S, followed by depositing a dielectric layer over the semiconductor substrate 102 between the fins. These fins are configured as channels of the LV transistors 100L.

FIG. 1E shows a formation of a gate dielectric layer 116 and a gate dielectric layer 216 in the HV zone 100A and MV zone 100B, respectively, in the semiconductor substrate 102. In some embodiments, the material layer of the gate dielectric layer 116 and the gate dielectric layer 216 includes silicon oxide, silicon nitride, silicon oxynitride or other suitable dielectric materials. The gate dielectric layer 116 or 216 may be formed by thermal oxidation by reaction of oxygen atoms with silicon atoms of the semiconductor substrate 102. Alternatively, the gate dielectric layer 116 or 216 can be formed by etching a recess in the semiconductor substrate 102 and depositing a dielectric material using CVD, PVD, ALD, ISSG or other suitable deposition methods. The gate dielectric layers 116 and 216 are formed on upper portions, e.g., on the surface 102S, of the semiconductor substrate 102. According to some embodiments, the gate dielectric layers 116 and 216 are formed through a same formation operation, e.g., a same thermal oxidation operation. The gate dielectric layers 116 and 216 may thus have substantially equal thicknesses H1. The thickness H1 is in a range between about 100 angstrom and about 200 angstrom, such as 150 angstrom.

According to some embodiments, FIG. 1E also shows a formation of a gate dielectric layer 316 on upper sides and lateral sides the fins in the LV zone 100C in the semiconductor substrate 102. In some embodiments, the material layer of the gate dielectric layer 316 includes silicon oxide, silicon nitride, silicon oxynitride or other suitable dielectric materials. The gate dielectric layer 316 may be formed by thermal oxidation by reaction of oxygen atoms with silicon atoms of the semiconductor substrate 102. Alternatively, the gate dielectric layer 316 can be formed by etching a recess in the semiconductor substrate 102 and depositing a dielectric material using CVD, PVD, ALD, ISSG or other suitable deposition methods. The gate dielectric layer 316 is formed on upper portions, e.g., on the surface 102S, of the semiconductor substrate 102. According to some embodiments, the gate dielectric layers 116 and 216 are formed through a same formation operation, e.g., a same thermal oxidation operation. Since the gate dielectric layer 316 is used in the LV transistor 100L that operates under an operation voltage lower than that of the HV transistors 100H or MV transistors 100M, the gate dielectric layer 316 has a thickness less than the thickness H1. According to some embodiments, the gate dielectric layer 316 is formed via a formation operation different from that forming the gate dielectric layer 116 or 216. According to some embodiments, the order of the formation of the gate dielectric layer 116 or 216 and the formation of the gate dielectric layer 316 are exchangeable.

Referring to FIG. 1F, Gate electrodes 218 and 318 are formed over the gate dielectric layers 216 and 316, respectively. The gate electrode 218 or 318 may include a conductive material, such as doped silicon. The gate electrodes 218 and 318 may serve as dummy gate electrodes or sacrificial gate electrodes at the moment, and will be replaced with functional gate electrodes or metal gate electrodes (see an electrode gates 219 and 319 shown in FIG. 1M). The gate electrode 218 or 318 may be formed by initially depositing a conductive material in a blanket manner over the upper surface of the gate dielectric layer 216 or 316, followed by a patterning operation to form the gate electrode 118. According to some embodiments, the gate electrode 218 or 318 overlaps the underlying gate dielectric layer 216 or 316, respectively. Further, the gate dielectric layer 216 may have a width greater than the gate electrode 218.

Referring to FIG. 1G, gate spacers 220 and 320 (also referred to as sidewall spacers) are formed on sidewalls of the gate electrode 218 or 318 in the MV zone 100B and LV zone 100C, respectively. In some embodiments, the gate spacers 220 or 320 are formed of dielectric layers, such as oxide, nitride, carbide, oxynitride, high-k dielectric materials, a combination thereof, or other suitable dielectric materials. In some embodiments, the gate spacers 220 or 320 include a single layer or multilayer structure. The gate spacers 220 or 320 may be formed by depositing one or more layers of dielectric materials in a conformal manner, followed by etching the horizontal portion of the dielectric materials. The vertical portion of the dielectric materials is left on the sidewalls of the gate electrodes 218 or 318 to thereby form the gate spacers 220 or 320.

Referring to FIG. 1H, epitaxial regions 322 are formed on the semiconductor substrate 102 on two sides of the respective gate electrodes 318. The epitaxial regions 322 are formed as source regions or drain regions of respective LV transistors 100V. The epitaxial regions 322 may be formed by etching the fins to form trenches on two sides of the gate spacers 320, followed by performing epitaxy operations, e.g., selective epitaxial growth (SEG), on these trenches. In an embodiment, the epitaxial regions 32 are formed over the exposed surface of the semiconductor substrate 102 by CVD, ALD, plasma-enhanced CVD (PECVD), high-density plasma CVD (HDPCVD), low-pressure CVD (LPCVD), metal-organic CVD (MOCVD), molecular beam epitaxy (MBE), or the like. According to some embodiments, the epitaxial regions 322 have an N-type dopant, such as arsenic or phosphor or a P-type dopant, such as boron or the like.

Referring to FIG. 1I, in some embodiments, a drain region 122 and a source region 124 for the HV transistor 100H are formed in the semiconductor substrate 102. The drain region 122 is arranged between the gate dielectric layer 116 and an adjacent isolation region 104. The source region 124 is arranged between the gate dielectric layer 116 and the adjacent isolation region 106. The drain region 122 and the source region 124 may include a dopant of a conductivity type, e.g., N-type, same as that of the well region 112. In some other embodiments, the drain region 122 and the source region 124 include a dopant of the other conductivity type, e.g., P-type, different from that of the well region 112. In some embodiments, a channel of the HV transistor 100H is formed between the drain region 122 and the source region 124 along a path along the bottom of the gate dielectric layer 116. The drain region 122 and the source region 124 have a dopant concentration greater than that of the well region 112 and 114, and may be doped regions formed by an ion implantation operation with an implant dose between about 1E12 atoms per square centimeter and about 1E18 atoms per square centimeter. Throughout the present disclosure, source/drain region(s) may refer to a source or a drain, individually or collectively dependent upon the context.

Referring to FIG. 1J, a doped region 126 is formed in the HV zone 100A of the semiconductor substrate 102. The doped region 126 is arranged between the isolation region 106 and an adjacent isolation region 104. The doped region 126 may include a dopant of a conductivity type, e.g., P-type, different from that of the drain region 122 or the source region 124. In some embodiments, the doped region 126 serves as a body contact to receive a biased voltage for the semiconductor substrate 102. The doped region 126 may be formed by an ion implantation operation with an implant dose between about 1E12 atoms per square centimeter and about 1E18 atoms per square centimeter.

According to some embodiments, doped regions 222 and 224 are formed in the MV zone 100B of the semiconductor substrate 102. The doped regions 222 and 224 are arranged on two sides of the gate dielectric layer 216. The doped regions 222 and 224 may include a dopant of a conductivity type, e.g., P-type, different from that of the drain region 122 or the source region 124, or N-type same as that of the drain region 122 or the source region 124 depending on the conductivity type of the MV transistor 100M. In some embodiments, the doped regions 222 and 224 serve as a source region and a drain region, respectively, of the MV transistor 100M. The doped regions 222 and 224 may be formed by an ion implantation operation with an implant dose between about 1E12 atoms per square centimeter and about 1E18 atoms per square centimeter. The doped regions 222 and 224 may be formed together with the formation of the doped regions 122 and 124 or the doped region 126, depending upon the conductivity type of the doped regions 222 and 224.

According to some embodiments, the steps shown in FIGS. 1H, 1I and 1J are interchangeable. According to some embodiments, the formation of the MV transistors 100M as planar transistors and the formation of the LV transistors 100L as FinFETs described with reference to the previous figures are shown for illustrative purposes only. The MV transistors 100M may be alternatively formed of planar transistors, e.g., a FinFET, a gate-all-around FET (GAAFET), a nanowire FET, a nanosheet FET, or other suitable non-planar FET devices. Further, the LV transistors 100L may be alternatively formed of other non-planar transistors, e.g., a GAAFET, a nanowire FET, a nanosheet FET, or other suitable non-planar FET devices.

Referring to FIG. 1K, subsequent to the formation of the MV transistors 100M and LV transistors 100L, an interconnect structure 110 is formed over the semiconductor substrate 102 across the HV zone 100A, MV zone 100B and LV zone 100C. Initially, a first interlayer dielectric (ILD) layer 130 is deposited on the semiconductor substrate 102. The first ILD layer 130 may include a dielectric material, such as silicon oxide. Other dielectric materials, such as silicon nitride, silicon oxynitride, or silicon carbide may also be used in the first ILD layer 130. The first ILD layer 130 may be deposited using CVD, PVD, ALD, spin coating, or other suitable deposition operations. According to some embodiments, a planarization operation, e.g., chemical mechanical polishing (CMP), mechanical grinding, or other etching operation, may be used to planarize the upper surface of the first ILD layer 130 and level the upper surface of the first ILD layer 130 with the upper surface of the gate electrodes 218 and 318.

Referring to FIG. 1L, an etching operation is performed to remove the gate electrodes 218 and 318. According to some embodiments, the etching operation also removes the gate dielectric layer 216 or the gate dielectric layer 316. The etching operation may include a dry etch, a wet etch, an RIE, or the like. A plurality of recesses 230R and 330R are formed in the first ILD layer 130 in the MV zone 100B and LV zone 100C accordingly. A portion of an upper surface of the gate dielectric layer 216 in the MV zone 100B or a portion of the semiconductor substrate 102 in the LV zone 100C are thus exposed.

Referring to FIG. 1M, a gate electrode 219 is formed in the recess 230R in the MV zone 100B in place of the gate electrode 218. Similarly, one or more gate electrodes 319 are formed in the recess 330R in the LV zone 100C in place of the gate electrodes 318. The gate electrode 219 or 319 may include a plurality of layers formed of conductive materials, such as tungsten (W), copper (Cu), cobalt (Co), aluminum (Al), nickel (Ni), tantalum (Ta), titanium (Ti), molybdenum (Mo), palladium (Pd), platinum (Pt), ruthenium (Ru), iridium (Ir) silver (Ag), gold (Au), titanium nitride (TiN), tantalum nitride (TaN), a combination thereof, or other suitable materials. According to some embodiments where the gate dielectric layer 216 or 316 is removed during the removal of the gate electrode 218 or 318, another gate dielectric layer is formed in the recess 230R or 330R prior to the deposition of the aforementioned materials of the gate electrode 219 or 319. According to some embodiments, a high-k dielectric layer is deposited over the gate dielectric layer 216 or 316 before the deposition of the conductive materials of the gate electrode 219 or 319. The gate electrode 219 is flushed with the top of the gate spacers 220 and the upper surface of the first ILD layer 130.

The formation of the gate electrode 219 and the formation of the gate electrode 319 may be performed through a same operation or separate operations. According to some embodiments, the gate electrode 119 and the gate electrodes 219 share one or more conductive layers in common, and these common conductive layers are deposited at the same time using the shared deposition operation.

Referring to FIG. 10 a second ILD layer 140 is deposited over the first ILD layer 130. The material, configuration and method of forming for the second ILD layer 140 may be similar to those for the first ILD layer 130. A third ILD layer 150 is deposited over the second ILD layer 140. The material, configuration and method of forming for the third ILD layer 150 may be similar to those for the first ILD layer 130 or the second ILD layer 140. A plurality of recesses 150R and 350R are formed in the third ILD layer 150 in the HV zone 100A or LV zone 100C. The recesses 150R and 350R may be formed at the same time using the same lithography and etching operations. The etching operation may include a dry etch, a wet etch, an RIE, or the like.

FIG. 10 shows a formation of a conductive layer 152 and a conductive line 352 in the recesses 150R and 350R in the HV zone 100A and LV zone 100C, respectively. The formations of the conductive layer 152 and the conductive line 352 may be performed at the same time using the same deposition operations, e.g., CVD, PVD, ALD, or other suitable deposition operations. The conductive layer 152 and the conductive line 352 are formed of the same material. The conductive layer 152 and the conductive line 352 may be formed of metal-based materials with a high electrical resistance, such as titanium-based metal, aluminum-based metal, nickel-chromium, or the like. In some embodiments, the conductive layer 152 and the conductive line 352 are formed of titanium nitride. According to some embodiments, the conductive layer 152 and the conductive line 352 include a resistance in a range between 300 and about 1000 Ω/sq. The conductive layer 152 and the conductive line 352 are formed in a same tier, i.e., the third ILD layer 150, of an interconnect structure 110 over the HV transistor 100H and the LV transistor 100L. According to some embodiments, the conductive layer 152 at least partially overlaps the gate dielectric layer 116. The conductive layer 152 may extend horizontally to overlap an entirety of the gate dielectric layer 116 from a cross-sectional view. The conductive layer 152 may overlap a portion of the drain region 112 or the source region 114 from a cross-sectional view.

According to some embodiments, the conductive layer 152 is configured as a gate electrode of the HV transistor 100H, where the gate dielectric layer 116 and the ILD layers 130, 140 together server as the gate dielectric layer of the HV transistor 100H. A vertical distance H2 between the conductive layer 152 and the gate dielectric layer 116 is in a range between about 600 angstrom and about 800 angstrom, such as 700 angstrom. The range of the distance H1+H2, that is equal to a bottom surface of the conductive layer 152 and a bottom surface of the gate dielectric layer 116, in a range between about 700 angstrom and about 1000 angstrom plays an important role for the capability of withstanding high operation voltage of the HV transistor 100H. On one hand, if the distance H1+H2 is made less than about 700 angstrom, the thickness of the ILD layers 130, 140 may not be sufficient to withstand the high operation voltage of the HV transistor 100H. On the other hand, if the distance H1+H2 is made greater than about 1000 angstrom, the voltage potential of the conductive layer 152 may not be sufficient to redistribute the electrical field around the gate dielectric layer 116 for reducing the risk of high-voltage breakdown.

As discussed previously, as illustrated in FIG. 10, the conductive line 352 is disposed directly over the LV transistor 100L. However, this embodiment is not to be limiting. The conductive line 352 can be disposed in other locations in the LV zone100C but not directly over the LV transistor 100L.

According to some embodiments, the thickness H1 is greater than the thickness of the gate dielectric layer 316 in the LV zone 100C. For example, the gate dielectric layer 316 has a thickness less than about 100 angstrom, less than about 50 angstrom, or less than about 20 angstrom.

Referring to FIG. 1P, a fourth ILD layer 160 is deposited over the third ILD layer 150. The material, configuration and method of forming for the fourth ILD layer 160 may be similar to those for the first ILD layer 130, the second ILD layer 140 or the third ILD layer 150. A plurality of conductive vias are formed through the first ILD layer 130, the second ILD layer 140, the third ILD layer 150 or the fourth ILD layer 160. For example, a conductive via 164 is formed through the fourth ILD layer 160 and electrically connected to the conductive layer 152. Similarly, conductive vias 172, 174 and 176 are formed through the fourth ILD layer 160, the third ILD layer 150, the second ILD layer 140 and the first ILD layer 130 in the HV zone 100A, and electrically connected to the drain region 122, the source region 124 and the doped region 126, respectively.

Likewise, conductive via 262 is formed through the fourth ILD layer 160, the third ILD layer 150 and the second ILD layer 140 in the MV zone 100B, and electrically connected to the respective gate electrode 219, and conductive vias 264 and 266 are formed through the fourth ILD layer 160, the third ILD layer 150, the second ILD layer 140 and the first ILD layer 130 in the MV zone 100B, and electrically connected to the respective doped regions 222 and 224, respectively.

Additionally, conductive vias 362 are formed through the fourth ILD layer 160, the third ILD layer 150 and the second ILD layer 140 in the LV zone 100C, and electrically connected to the respective gate electrodes 319, and conductive vias 364 are formed through the fourth ILD layer 160 in the LV zone 100C and electrically connected to two ends of the conductive line 352. Conductive vias 372 are formed through the fourth ILD layer 160, the third ILD layer 150 and the second ILD layer 140 and extending into the first ILD layer 130 in the LV zone 100C, and electrically connected to the respective source/drain regions 322.

According to some embodiments, the conductive vias 164, 172, 174, 176, 262, 264, 266, 362 and 372 are formed of a conductive material, such as tungsten, titanium, tantalum, aluminum, copper, gold, silver, or the like. The conductive vias 164, 172, 174, 176, 262, 264, 266, 362 and 372 may be formed by etching vias from the upper surface of the fourth ILD layer 160 to expose the upper surfaces of the gate electrode 219, the conductive layer 152, the drain region 122, the source region 124, the doped region 126, the gate electrodes 319, the doped regions 222 and 224, the conductive line 352 and the source/drain regions 322, respectively. A conductive material of the conductive vias 164, 172, 174, 176, 262, 264, 266, 362 and 372 is deposited in the etched vias and over the upper surface of the fourth ILD layer 160. According to some embodiments, a planarization operation, e.g., CMP, is performed to remove the excess portion of the conductive material and level the upper surfaces of the conductive vias 164, 172, 174, 176, 262, 264, 266, 362 and 372 with the upper surface of the fourth ILD layer 160.

According to some embodiments, the conductive layer 152 is arranged horizontally adjacent to the conductive via 162. In other words, the conductive layer 152 is arranged in a same tier of the interconnect structure 110 as the conductive via 172, 174, 176, 262, 264, 266, 362 or 372.

According to some embodiments, the high electrical resistance of the conductive line 352 is used to form a resistive element in a resistor-capacitor (RC) circuit associated with the LV transistor 100L. The conductive layer 152 for the HV transistor 100H is arranged to be formed along with the formation of the conductive line 352 during the formation of the RC circuit for the LV transistor 100L. The high-resistance conductive material used in forming the conductive line 352 can also be reused in forming the conductive layer 152 without difficulty. When compared to existing methods of forming HV transistors without the conductive layer 152, no cost is to be paid for providing an additional photomask for forming the conductive layer 152. Therefore, the processing cost and time can be reduced as compared to existing HV transistor structures.

Referring to FIG. 1Q, an IMD layer 170 is deposited over the fourth ILD layer 160. The material, configuration and method of forming for the IMD layer 170 may be similar to those for the ILD layers 130, 140, 150 and 160. A plurality of recesses (not separately shown) is etched in the IMD layer 170. A conductive material, such as tungsten, titanium, tantalum, aluminum, copper, gold, silver, or the like, is deposited in the recesses to form a conductive line 178 in the HV zone 100A, a conductive line 278 in the MV zone 100B and a conductive line 378 in the LV zone 100C. The conductive line 178 is electrically connected to the conductive layer 152 through the conductive vias 164. Likewise, the conductive line 278 is electrically connected to the gate electrode 219 through the conductive vias 262. Similarly, the conductive line 378 is electrically connected to the two ends of the conductive line 352 through the respective conductive vias 364. Although not separately shown in FIG. 1P, the IMD layer 170 further includes conductive lines electrically connected to the conductive vias 172, 174, 176, 262, 264, 266, 362 and 372.

According to some embodiments, the ILD layers 140, 150 and 160, and the IMD layer 170 (optionally including the first ILD layer 130) constitute the interconnect structure 110 over the HV transistor 100H, the MV transistor 100M and the LV transistor 100L. The conductive vias 164, 172, 174, 176, 262, 264, 266, 362 and 372 and the conductive lines 178, 278, 352, 378 are interconnected within the interconnect structure 110 for providing interconnections between overlying circuits and the HV transistor 100H, the MV transistor 100M and the LV transistor 100L. According to some embodiments, as discussed previously, the conductive layer 152 and the conductive line 352 are formed of a high-resistance conductive material, while the conductive vias 164, 172, 174, 176, 262, 264, 266, 362 and 372 and the conductive lines 178, 278 and 378 are formed of a low-resistance conductive material. As a result, the conductive layer 152 and the conductive line 352 are formed of a material different from that of the 164, 172, 174, 176, 262, 264, 266, 362 and 372 and the conductive lines 178, 278 and 378.

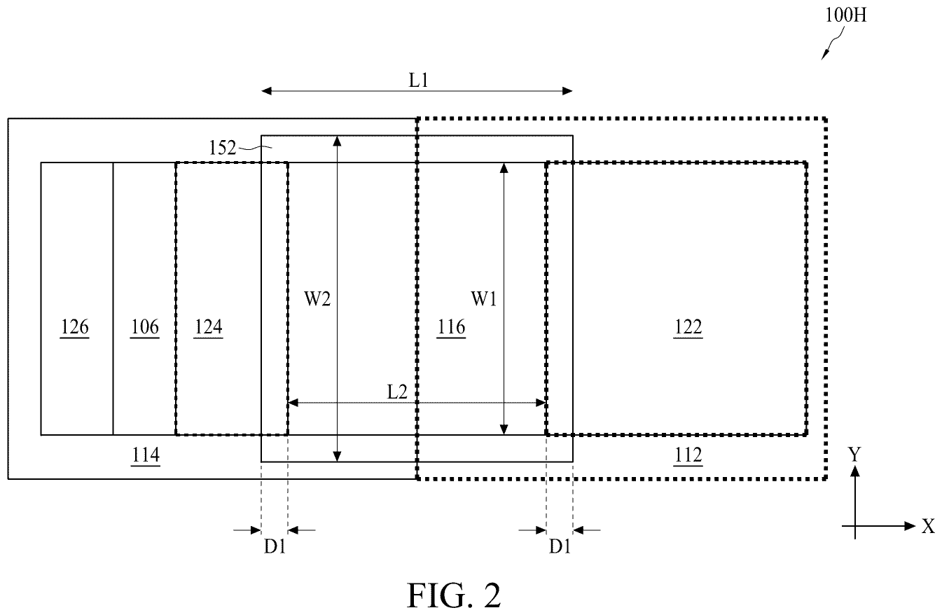

FIG. 2 shows a plan view of the HV transistor 100H, in accordance with some embodiments of the present disclosure. Referring to FIG. 2, the conductive layer 152 overlaps the gate dielectric layer 116 from a top-view perspective. The conductive layer 152 may include a length L1 measured in a lengthwise direction (X-axis) parallel to a line connecting the drain region 112 and the source region 114 and a width W1 measured in a widthwise direction (Y-axis) perpendicular to the lengthwise direction. According to some embodiments, the length L1 is substantially equal to or greater than a length L2 of the gate dielectric layer 116, and the width W1 is substantially equal to or greater than a width W2 of the gate dielectric layer 116. According to some embodiments, the conductive layer 152 extends in the lengthwise direction so that it overlaps a portion of the drain region 112 or the source region 114 by a width D1. A ratio of the width D1 to the width L1 is in a range between about 0% and about 20%. If the ratio of the width D1 to the width L1 is greater than about 20%, the conductive layer 152 may introduce undesired electrical field that interferes the original electrical field of the HV transistor 100H.

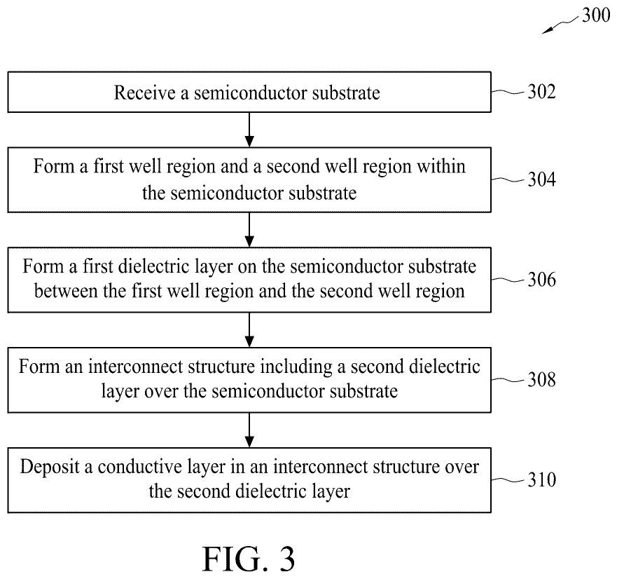

FIG. 3 shows a flowchart of a method 300 of manufacturing a semiconductor device, in accordance with some embodiments of the present disclosure. It shall be understood that additional steps can be provided before, during, and after the steps in method 300, and some of the steps described below can be replaced with other embodiments or eliminated. The order of the steps shown in FIG. 3 may be interchangeable. Some of the steps may be performed concurrently or independently.

At step 302, a semiconductor substrate is received. At step 304, a first well region and a second well region is formed within the semiconductor substrate.

At step 306, a gate dielectric layer is formed in the semiconductor substrate between the first well region and the second well region.

At step 308, an interconnect structure including a second dielectric layer is formed over the semiconductor substrate.

At step 310, a conductive layer is deposited in an interconnect structure over the second dielectric layer. The conductive layer serves as a first gate electrode of a first transistor in a first zone of the semiconductor substrate.

In accordance with some embodiments of the present disclosure, a method is provided. The method includes: receiving a semiconductor substrate; forming a first well region and a second well region within the semiconductor substrate; forming a first dielectric layer on the semiconductor substrate between the first well region and the second well region; forming an interconnect structure comprising a second dielectric layer over the semiconductor substrate; and depositing a conductive layer in the interconnect structure over the second dielectric layer. The conductive layer serves as a first gate electrode of a first transistor in a first zone of the semiconductor substrate.

In accordance with some embodiments of the present disclosure, a method is provided. The method includes: receiving a semiconductor substrate; forming a first dielectric layer on the semiconductor substrate; forming a first doped region and a second doped region in the semiconductor substrate on two sides of the first dielectric layer; depositing a second dielectric layer over the semiconductor substrate; and depositing a conductive layer over the first dielectric layer and overlapping the first dielectric layer from a top-view perspective. The conductive layer, the first doped region and the second doped region are configured as a gate electrode, a source region and a drain region, respectively, of a first transistor in a first zone of the semiconductor substrate.

In accordance with some embodiments of the present disclosure, a semiconductor structure including: a semiconductor substrate; a first well region and a second well region of a first conductivity and a second conductivity type, respectively, within the semiconductor substrate; a first dielectric layer in the semiconductor substrate between the first well region and the second well region; and an interconnect structure over the semiconductor substrate. The interconnect structure includes: a second dielectric layer; and a conductive layer disposed over the second dielectric layer and serving as a first gate electrode of a first-type transistor.

The foregoing outlines structures of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
receiving a semiconductor substrate;
forming a first well region and a second well region within the semiconductor substrate;
forming a first dielectric layer on the semiconductor substrate between the first well region and the second well region;
forming an interconnect structure comprising a second dielectric layer over the semiconductor substrate; and
depositing a conductive layer in the interconnect structure over the second dielectric layer, wherein the conductive layer serves as a first gate electrode of a first transistor in a first zone of the semiconductor substrate.

2. The method of claim 1, further comprising forming an isolation region in the semiconductor substrate and laterally surrounded by the first well region.

3. The method of claim 2, further comprising forming a source region within the first well region between the first dielectric layer and the isolation region.

4. The method of claim 2, further comprising forming a drain region in the second well region on a side of the first dielectric layer opposite to the isolation region.

5. The method of claim 1, wherein the first dielectric layer and at least a portion of the second dielectric layer serve as a gate dielectric layer of the first transistor.

6. The method of claim 5, further comprising forming a second gate electrode of a second transistor in a second zone of the semiconductor substrate prior to the forming of the conductive layer.

7. The method of claim 6, wherein the conductive layer resides at a first height greater than a second height at which the second gate electrode resides.

8. The method of claim 6, wherein the first transistor and the second transistor are associated with a planar transistor and a non-planar transistor, respectively.

9. The method of claim 6, the depositing of the conductive layer comprises depositing a conductive line over the second gate electrode, wherein the conductive layer and the conductive line are arranged in a same interconnect structure.

10. The method of claim 9, wherein the conductive layer and the conductive line are formed of a same high-resistance material.

11. A method, comprising:
receiving a semiconductor substrate;
forming a first dielectric layer on the semiconductor substrate;
forming a first doped region and a second doped region in the semiconductor substrate on two sides of the first dielectric layer;
depositing a second dielectric layer over the semiconductor substrate; and
depositing a conductive layer over the first dielectric layer and overlapping the first dielectric layer from a top-view perspective,
wherein the conductive layer, the first doped region and the second doped region are configured as a gate electrode, a source region and a drain region, respectively, of a first transistor in a first zone of the semiconductor substrate.

12. The method of claim 11, wherein the forming of the first dielectric layer comprises forming a third dielectric layer on the semiconductor substrate in a second zone of the semiconductor substrate.

13. The method of claim 12, wherein the first and third dielectric layers serve as gate dielectric layers of the first transistor and a second transistor, respectively, in the first zone and a second zone, respectively, of the semiconductor substrate.

14. The method of claim 13, wherein the first transistor operates under a first biasing voltage greater than a second biasing voltage under which the second transistor operates.

15. The method of claim 12, wherein the first and third dielectric layers are formed by a same formation operation.

16. The method of claim 12, wherein a portion of the third dielectric layer between the conductive layer and the first dielectric layer is free of any conductive material.

17. The method of claim 11, wherein a vertical distance between a bottom surface of the conductive layer and a bottom surface of the first dielectric layer is between about 700 angstrom and about 1000 angstrom.

18. A semiconductor structure, comprising:
a semiconductor substrate;
a first well region and a second well region of a first conductivity and a second conductivity type, respectively, within the semiconductor substrate;
a first dielectric layer in the semiconductor substrate between the first well region and the second well region; and
an interconnect structure over the semiconductor substrate and comprising:
a second dielectric layer; and
a conductive layer disposed over the second dielectric layer and serving as a first gate electrode of a first-type transistor.

19. The semiconductor structure of claim 18, further comprising a conductive line electrically coupled to the conductive layer, wherein the conductive line and the conductive layer are formed of different materials.

20. The semiconductor structure of claim 18, further comprising a second gate electrode arranged disposed over the semiconductor substrate and associated with a second-type transistor, wherein the interconnect structure further comprises a resistive element, and the conductive layer and the resistive element are formed of a same high-resistance material.
